(19) United States
(12) Patent Application Publication
(10) Pub. No.: US 2007/0029565 A1
(43) Pub. Date: Feb. 8, 2007

(54) Blue light-emitting phosphor and light-emitting device using the same

(75) Inventors: Masatsugu Masuda, Higashihiroshima-shi (JP); Toyonori Uemura, Higashihiroshima-shi (JP); Tsukasa Inoguchi, Kitakatsuragi-gun (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/497,663

(22) Filed: Aug. 1, 2006

(30) Foreign Application Priority Data
Aug. 2, 2005 (JP) JP2005-223783

(51) Int. Cl. H01L 33/00; C09K 11/08; C09K 11/77

(52) U.S. Cl. 257/98; 252/301.4 R; 252/301.4 F

(57) ABSTRACT

A blue light-emitting phosphor emitting light with high efficiency by ultraviolet light of long wavelength as well as blue (to violet) light of short wavelength emitted from a semiconductor light-emitting element, particularly by the light having the wavelength in the range from 380 nm to 430 nm, is provided. A light-emitting device exhibiting high luminance and stable chromaticity is also provided by using the blue light-emitting phosphor. The blue light-emitting phosphor includes a divalent europium-activated or divalent europium- and manganese-activated aluminate phosphor, substantially represented by the general formula: a[(MI_{1-c-d}Sr_{c}Eu_{d})(Mg₁₋ₑMₑ)]O.bAl₂O₃, where MI represents at least one kind of element selected from Ca and Ba, and a, b, c, d and e are numbers satisfying 0.1≦a/b≦1.0, 0.2≦c≦0.8, 0.01≦d≦0.5, and 0≦e≦0.05.

This nonprovisional application is based on Japanese Patent Application No. 2005-223783 filed with the Japan Patent Office on Aug. 2, 2005, the entire contents of which are hereby incorporated by reference.

### BACKGROUND OF THE INVENTION

1. Field of the Invention

The present invention relates to a blue light-emitting phosphor that highly efficiently emits light by primary light emitted from a light-emitting element, and a light-emitting device using the same in a wavelength conversion unit.

2. Description of the Background Art

A light-emitting device having a semiconductor light-emitting element and a phosphor in combination has attracted attention as a light-emitting device of next generation that is expected to realize low power consumption, downsizing, and to have high luminance and color reproducibility of wide range, for which research and development have been conducted vigorously. As the primary light emitted from a light-emitting element, generally, light within the range from ultraviolet light of long wavelength to blue light, i.e., from 380 nm to 480 nm in wavelength, is used. Wavelength conversion units using various phosphors applicable to such use have been proposed.

While the peak wavelength of the primary light emitted from the light-emitting element slightly varies depending on fabrication conditions, the peak wavelength of the phosphor hardly deviates from a designed value. Thus, the use of a blue light-emitting phosphor, a green light-emitting phosphor and/or a red light-emitting phosphor, emitting light by the primary light emitted from the light-emitting element, is more advantageous than the use of the primary light in that chromaticity as designed can be obtained stably as a light-emitting device. However, not all the phosphors can emit light efficiently with respect to the primary light emitted from the light-emitting element, and particularly, there is a demand for a blue light-emitting phosphor that can emit light with high efficiency with respect to excitation of ultraviolet light of long wavelength as well as blue (to violet) light of short wavelength.

The blue light-emitting phosphor emitting light with excitation of the ultraviolet light of long wavelength as well as blue (to violet) light of short wavelength may include divalent europium-activated BaMgAl₁₀O₁₇:Eu and (Sr,Ba,Ca)₁₀(PO₄)₆.Cl₂:Eu. However, they are poor in luminous efficiency, for which improvement is demanded. Further, although various oxynitride matrices have been investigated focusing on the above problem, any blue light-emitting phosphor that can emit light with high efficiency has not been obtained.

Japanese Patent Laying-Open No. 49-077893 discloses a divalent europium-activated BaMgAl₁₀O₁₇:Eu phosphor. It however is used for a low-pressure or high-pressure mercury vapor discharge lamp, and there is no description about luminous efficiency with respect to excitation of ultraviolet light of long wavelength or blue (to violet) light of short wavelength. Japanese Patent Laying-Open No. 03-106988 discloses an europium- and manganese-activated alkaline earth metal aluminate phosphor having part of Ba substituted with Sr and/or Ca. The method however is intended to provide a phosphor showing a small change in color of the emitted light while the lamp is on. There is no description about luminous efficiency with respect to excitation of ultraviolet light of long wavelength or blue (to violet) light of short wavelength.

Japanese Patent Laying-Open No. 2001-172623 discloses a phosphor formed of a mixture of a divalent europium-activated alkaline metal chlorophosphate phosphor and a divalent manganese-activated alkaline earth aluminate phosphor. The phosphor however is intended to obtain high luminous output under excitation of ultraviolet light at 185 nm and 254 nm, and there is no description about luminous efficiency with respect to excitation of ultraviolet light of long wavelength or blue (to violet) light of short wavelength.

Japanese Patent Laying-Open No. 2002-003836 discloses a blue phosphor having silicon oxide dissolved in an alkaline earth metal aluminate compound, and Japanese Patent Laying-Open No. 2002-003837 discloses a blue phosphor having silicon oxide and at least one kind of rare earth oxide selected from yttrium oxide and gadolinium oxide dissolved in an alkaline earth metal aluminate compound. These however are intended to improve luminous output under excitation of ultraviolet light of 254 nm, for example, and there is no description about luminous efficiency with respect to excitation of ultraviolet light of long wavelength or blue (to violet) light of short wavelength.

As such, in the conventional art, there has not been obtained a blue phosphor that exhibits high luminous output and stable chromaticity with respect to excitation of ultraviolet light of long wavelength as well as blue (to violet) light of short wavelength.

### SUMMARY OF THE INVENTION

An object of the present invention is to provide a blue light-emitting phosphor that emits light with high efficiency by ultraviolet light of long wavelength as well as blue (to violet) light of short wavelength emitted from a semiconductor light-emitting element, particularly by light having the wavelength within the range from 380 nm to 430 nm, and to provide a light-emitting device exhibiting high luminance and stable chromaticity by using the same.

The present invention relates to a blue light-emitting phosphor that includes a divalent europium-activated, or divalent europium- and manganese-activated aluminate phosphor, substantially represented by the following general formula (1):
a[(MI_{1-c-d}Sr_{c}Eu_{d})(Mg₁₋ₑMnₑ)]O.bAl₂O₃ (1)
(in the formula (1), MI represents at least one kind of element selected from Ca and Ba, and a, b, c, d and e are numbers satisfying 0.1≦a/b≦1.0, 0.2≦c≦0.8, 0.01≦d≦0.5, and 0≦e≦0.05).

In the blue light-emitting phosphor according to the present invention, it is preferable that MI in the general formula (1) above is Ba.

The blue light-emitting phosphor according to the present invention preferably includes the divalent europium-activated aluminate phosphor with the value of e in the general formula (1) above being 0.

Further, the present invention relates to a light-emitting device that includes: a light-emitting element emitting primary light; and a wavelength conversion unit absorbing at least part of the primary light and emitting secondary light having a wavelength equal to or longer than a wavelength of the primary light; wherein the wavelength conversion unit is made of at least one kind of phosphor, and the phosphor includes the blue light-emitting phosphor as described above.

In the light-emitting device of the present invention, it is preferable that the wavelength conversion unit is made of the blue light-emitting phosphor, a green light-emitting phosphor and a red light-emitting phosphor, and in a light path of the wavelength conversion unit, the phosphors are stacked in order from the one emitting the secondary light of longer wavelength.

The green light-emitting phosphor preferably includes at least one kind of phosphor selected from:

a divalent europium- and manganese-activated aluminate phosphor substantially represented by the following general formula (2):
a(MII,Eu_{f},Mn_{g})O.bAl₂O₃ (2)
(in the formula (2), MII represents at least one kind of element selected from Mg, Ca, Sr, Ba and Zn, and a, b, f and g are numbers satisfying a>0, b>0, 0.1≦a/b≦1.0, and 0.3≦g/f≦5.0);

a divalent europium-activated silicate phosphor substantially represented by the following general formula (3):
2(MIII₁₋ₕEuₕ)O.SiO₂ (3)
(in the formula (3), MIII represents at least one kind of element selected from Mg, Ca, Sr and Ba, and h is a number satisfying 0.005≦h≦0.10); and

a divalent europium-activated strontium aluminate phosphor substantially represented by the following general formula (4):
(Sr₁₋ₘEuₘ)O.Al₂O₃ (4)
(in the formula (4), m is a number satisfying 0.0001≦m≦0.3).

Further, the red light-emitting phosphor preferably includes a divalent europium-activated nitride phosphor substantially represented by the following general formula (5):
(MIII₁₋ₖEuₖ)MIVSiN₃ (5)
(in the formula (5), MIII represents at least one kind of element selected from Mg, Ca, Sr and Ba, MIV represents at least one kind of element selected from Al, Ga, In, Sc, Y, La, Gd and Lu, and k is a number satisfying 0.001≦k≦0.05).

In the light-emitting device of the present invention, it is preferable that the light-emitting element is a gallium nitride (GaN)-based semiconductor, and the primary light emitted from the light-emitting element has a peak wavelength in a range from 380 nm to 430 nm.

According to the present invention, it is possible to obtain a blue light-emitting phosphor that can efficiently absorb light emitted from a light-emitting element and can highly efficiently emit blue light, particularly a blue light-emitting phosphor that emits light with high efficiency by ultraviolet light of long wavelength as well as blue (to violet) light of short wavelength. Further, it is also possible to obtain a light-emitting device, by using the relevant blue light-emitting phosphor in its wavelength conversion unit, that can efficiently absorb light emitted from the light-emitting element and can emit white light having high luminance and stable chromaticity.

Since the blue light-emitting phosphor and the light-emitting device using the same according the present invention ensure significantly improved luminous efficiency, they are suitably applicable to a light-emitting device of low power consumption or of small size, or to a light-emitting device for which high luminance and color reproducibility of wide range are required.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view illustrating a light-emitting device as an embodiment of the present invention.

FIG. 2 shows distribution of emission spectrum of a blue light-emitting phosphor as an embodiment of the present invention.

### DESCRIPTION OF THE PREFERRED EMBODIMENTS

In the present invention, it is possible to obtain a blue light-emitting phosphor that emits light highly efficiently with respect to excitation of ultraviolet light of long wavelength as well as blue (to violet) light of short wavelength, by substituting a small or large part of Ca and/or Ba with Sr.

More specifically, the blue light-emitting phosphor of the present invention is a blue light-emitting phosphor made of a divalent europium-activated, or divalent europium- and manganese-activated aluminate phosphor, which is substantially represented by the following general formula (1):
a[(MI_{1-c-d}Sr_{c}Eu_{d})(Mg₁₋ₑMnₑ)]O.bAl₂O₃ (1)
(in the formula (1), MI represents at least one kind of element selected from Ca and Ba, and a, b, c, d and e are numbers satisfying: 0.1≦a/b≦1.0, 0.2≦c≦0.8, 0.01≦d≦0.5, and 0≦e≦0.05).

The blue light-emitting phosphor of the present invention satisfying the above general formula (1) can efficiently absorb excitation light particularly when irradiated with ultraviolet light of long wavelength as well as blue (to violet) light of short wavelength having the peak wavelength within the range from 380 nm to 430 nm, and can emit blue light with high efficiency.

In the present invention, MI in the general formula (1) is preferably Ba. In this case, the configuration with Ba and Sr allows the divalent europium to be more stable, ensuring emission of brighter light.

In the present invention, Sr is prepared such that the value of c in the general formula (1) falls within the range from 0.2 to 0.8. In doing so, when irradiated with ultraviolet light of long wavelength or blue (to violet) light of short wavelength, blue light of extremely high efficiency can be obtained. If the value of c is less than 0.2, luminous efficiency would be degraded considerably, which is not practical. If the value of c exceeds 0.8, although visual luminance may increase as the peak wavelength is shifted to the long wavelength side, conversion efficiency would be degraded considerably, which is not practical. The value of c within the range from 0.4 to 0.6 is more suitable for use in the present invention.

In the present invention, Eu is prepared such that the value of d in the general formula (1) falls within the range from 0.01 to 0.5. If the value of d is less than 0.01, the content of the activator ions Eu²⁺ constituting the luminescence center would be insufficient, in which case desired emission of light cannot be obtained. If the value of d exceeds 0.5, emission of light would be degraded due to concentration quenching that is considered to be attributable to interaction of the activator, for example.

In the present invention, Mn is prepared such that the value of e in the general formula (1) falls within the range from 0 to 0.05. If the value of e exceeds 0.05, the green light-emitting component would become too intense, which would considerably degrade luminance of white light obtained from combination of the blue light-emitting phosphor, red light-emitting phosphor and green light-emitting phosphor, which is not practical. It is particularly preferable to set the value of e to zero.

The present invention also relates to a light-emitting device including a light-emitting element that emits primary light, and a wavelength conversion unit that absorbs at least part of the primary light and emits secondary light having a wavelength equal to or longer than the wavelength of the primary light, wherein the wavelength conversion unit is made of at least one kind of phosphor, and the phosphor includes the blue light-emitting phosphor of the present invention. In particular, the present invention typically relates to a light-emitting device having the wavelength conversion unit made of a blue light-emitting phosphor, a green light-emitting phosphor and a red light-emitting phosphor.

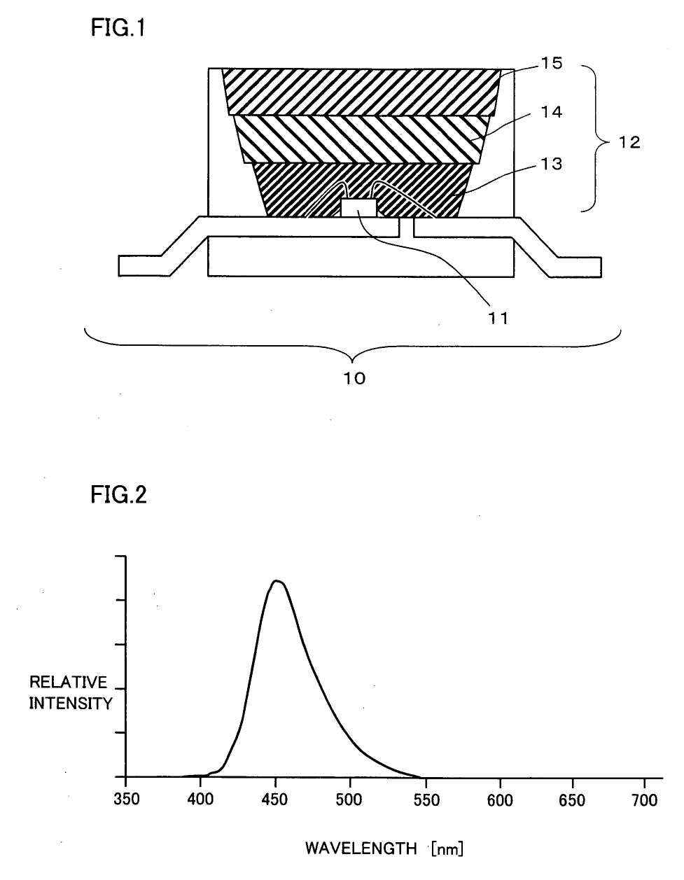

In FIG. 1, a light-emitting device 10 includes a light-emitting element 11 that emits primary light, and a wavelength conversion unit 12 that absorbs at least part of the primary light and emits secondary light having a wavelength longer than that of the primary light. Wavelength conversion unit 12 is made of a red light-emitting phosphor 13, a green light-emitting phosphor 14, and the blue light-emitting phosphor 15 of the present invention, wherein the three phosphors are stacked to be 1:1:1 in thickness, for example.

As the light-emitting element in the light-emitting device of the present invention, a gallium nitride (GaN)-based semiconductor is preferably used. Further, the peak wavelength of the primary light emitted from the light-emitting element preferably falls within the range from 380 nm to 430 nm. With the peak wavelength of the primary light of 380 nm or more, luminous efficiency of the light-emitting element is favorable, which is practical. With the peak wavelength of 430 nm or less, luminous efficiency of the blue light-emitting aluminate phosphor and that of the green light-emitting aluminate phosphor are favorable, which is practical. Particularly, the peak wavelength of the primary light falling within the range from 395 nm to 415 nm is suitable for use in the present invention.

FIG. 2 shows emission spectrum of the blue light-emitting phosphor of the present invention having a composition of (Ba_{1.5}Sr_{0.4}Eu_{0.1})MgAl₁₀O₁₇, with the peak wavelength of the secondary light near 456 nm.

In the light-emitting device of the present invention, from the standpoint of achieving emission of brighter light, it is preferable that a plurality of phosphors including the blue light-emitting phosphor of the present invention are stacked in order from the phosphor emitting secondary light of longer wavelength, to thereby form a light path. It is also preferable that the phosphors include the blue light-emitting phosphor, green light-emitting phosphor, and red light-emitting phosphor.

The green light-emitting phosphor used in the wavelength conversion unit in the light-emitting device of the present invention is preferably formed of at least one kind of phosphor selected from:

a divalent europium- and manganese-activated aluminate phosphor substantially represented by the following general formula (2):
a(MII,Eu_{f},Mn_{g})O.bAl₂O₃ (2)
(in the formula (2), MII represents at least one kind of element selected from Mg, Ca, Sr, Ba and Zn, and a, b, f and g are numbers satisfying a>0, b>0, 0.1≦a/b≦1.0, and 0.3≦g/f≦5.0);

a divalent europium-activated silicate phosphor substantially represented by the following general formula (3):
2(MIII₁₋ₕEuₕ)O.SiO₂ (3)
(in the formula (3), MIII represents at least one kind of element selected from Mg, Ca, Sr and Ba, and h is a number satisfying 0.005≦h≦0.10); and

a divalent europium-activated strontium aluminate phosphor substantially represented by the following general formula (4):
(Sr₁₋ₘEuₘ)O.Al₂O₃ (4)
(in the formula (4), m is a number satisfying 0.0001≦m≦0.3). When the above-described green light-emitting phosphor is used in combination with the blue light-emitting phosphor of the present invention satisfying the general formula (1), a light-emitting device that emits particularly bright light can be obtained.

In the BAM:Eu,Mn phosphor substantially represented by the general formula (2), the values of a and b in the formula are set such that a>0, b>0, and 0.1≦a/b≦1.0. When the value of g/f is 0.3 or greater, the amount of Mn²⁺ does not become too small, so that sufficient emission of green light is obtained. With the value of g/f of 5.0 or smaller, sufficient energy is transferred to Mn²⁺, so that sufficient emission of green light is obtained as well.

In the alkaline earth silicate phosphor substantially represented by the general formula (3), when the value of h in the formula is 0.005 or greater, Eu²⁺ is contained in a sufficient amount, so that sufficient emission of light is ensured. With the value of h of 0.10 or smaller, degradation in emission of light due to concentration quenching can be avoided.

In the strontium aluminate phosphor substantially represented by the general formula (4), when the value of m in the formula is 0.0001 or greater, Eu²⁺ is contained in a sufficient amount, so that sufficient emission of light is ensured. When it is 0.3 or smaller, degradation in emission of light due to concentration quenching can be avoided.

In the light-emitting device of the present invention, although the plurality of phosphors may be stacked in order from the one emitting secondary light of longer wavelength as described above, in the case where a divalent europium- and manganese-activated aluminate phosphor substantially represented by the general formula (2): a(MII,Eu_{f},Mn_{g})O.bAl₂O₃ (where MII represents at least one kind of element selected from Mg, Ca, Sr, Ba and Zn, and a, b, f and g are numbers satisfying a>0, b>0, 0.1≦a/b≦1.0, and 0.3≦g/f≦5.0) is used as the green light-emitting phosphor, it is also possible to use the blue light-emitting phosphor of the present invention and the relevant green light-emitting phosphor by mixing them together. In this case as well, the similar functions and effects as in the case of stacking separate blue light-emitting phosphor and green light-emitting phosphor are obtained.

Further, the red light-emitting phosphor used in the wavelength conversion unit in the light-emitting device of the present invention is preferably a divalent europium-activated nitride phosphor substantially represented by the following general formula (5):
(MIII₁₋ₖEuₖ)MIVSiN₃ (5)
(in the formula (5), MIII represents at least one kind of element selected from Mg, Ca, Sr and Ba, MIV represents at least one kind of element selected from Al, Ga, In, Sc, Y, La, Gd and Lu, and k is a number satisfying 0.001≦k≦0.05). When such a red light-emitting phosphor is used in combination with the blue light-emitting phosphor of the present invention satisfying the general formula (1), a light-emitting device emitting particularly bright light can be obtained.

In the nitride phosphor substantially represented by the general formula (5), when the value of k in the formula is 0.001 or greater, Eu²⁺ is contained in a sufficient amount, ensuring emission of sufficient light. When it is 0.05 or smaller, degradation in emission of light due to concentration quenching can be avoided.

It is noted that the compositions of the respective phosphors can be analyzed and evaluated by ICP (inductively coupled plasma) spectrometry, ion-exchange chromatography or the like.

### EXAMPLES

Hereinafter, the present invention will be described in more detail by giving examples, although the present invention is not limited thereto.

### Example 1

24.98 g of BaCO₃ (barium carbonate), 14.95 g of SrCO₃ (strontium carbonate), 21.35 g of MgCO₃ (magnesium carbonate), 134.26 g of Al₂O₃ (aluminum oxide), and 4.46 g of Eu₂O₃ (europium oxide) were measured accurately and mixed sufficiently by a ball mill. The mixture of raw materials was introduced into an alumina crucible with a lid, and baked at the temperature of 1550° C. in a reducing atmosphere (H₂: 5 volume %, N₂: 95 volume %) for four hours. The baked mixture was milled into fine particles by the ball mill, and then rinsed sufficiently with warm purified water. The rinsed phosphor particles were filtered and dried, whereby the blue light-emitting phosphor having the composition of (Ba_{0.5}Sr_{0.4}Eu_{0.1})MgAl₁₀O₁₇ was prepared.

### Examples 2-8

Blue light-emitting phosphors having compositions shown in Table 1 were prepared in a similar manner as in Example 1 above.

### Comparative Examples 1-8

Blue light-emitting phosphors having compositions shown in Table 1 were prepared.

The compositions of the blue light-emitting phosphors prepared in Examples 1-8 and Comparative Examples 1-8 were confirmed by ICP spectrometry.

<Evaluation of Luminance>

For the blue light-emitting phosphors of Examples 1-8 and Comparative Examples 1-8 obtained as described above, luminance under excitation when using excitation lights having the wavelengths shown in Table 1 was measured. The results of Examples 1-8 are indicated as relative values with respect to the corresponding results of Comparative Examples 1-8 each being set to 100%. The results are shown in Table 1.

### Example 9

A light-emitting device having the configuration shown in FIG. 1 was fabricated using the blue light-emitting phosphor prepared in Example 1. As the light-emitting element 11 in FIG. 1, a gallium nitride (GaN)-based light-emitting diode having the peak wavelength at 410 nm was used. To form wavelength conversion unit 12, a red light-emitting phosphor 13 having a composition of (Ca_{0.99}Eu_{0.01})AlSiN₃, a green light-emitting phosphor 14 having a composition of (Ba_{0.85}Eu_{0.15})(Mg_{0.70}Mn_{0.30})Al₁₀O₁₇, and the blue light-emitting phosphor 15 having the composition of (Ba_{0.5}Sr_{0.4}Euo_{0.1})MgAl₁₀O₁₇ according to Example 1 were stacked such that the three light-emitting phosphors have the thicknesses of blue light-emitting phosphor: green light-emitting phosphor: red light-emitting phosphor=1:1:1.

### Comparative Example 9

A light-emitting device was fabricated in a similar manner as in Example 9, except that the red light-emitting phosphor and the green light-emitting phosphor having the same compositions as those used in Example 9 and the blue light-emitting phosphor prepared in Comparative Example 1 were mixed in the mass ratio of blue light-emitting phosphor: green light-emitting phosphor: red light-emitting phosphor=2.5:1.6:1.0 and used for the wavelength conversion unit.

### Examples 10-16

Light-emitting devices were fabricated in a similar manner as in Example 9, except that gallium nitride (GaN)-based light-emitting diodes having the peak wavelengths shown in Tables 2 and 3 were used as light-emitting elements 11, and that the phosphors having the compositions shown in Tables 2 and 3 were used as the phosphors emitting red, green and blue lights for use in wavelength conversion units 12.

### Comparative Examples 10-16

Light-emitting devices were fabricated in a similar manner as in Comparative Example 9, except that gallium nitride (GaN)-based light-emitting diodes having the peak wavelengths shown in Tables 2 and 3 were used as light-emitting elements 11, and that the phosphors having the compositions shown in Tables 2 and 3 were used as the phosphors emitting red, green and blue lights to be mixed together for use in the wavelength conversion units.

<Evaluation of Brightness and Color Temperature>

Brightness and color temperature were evaluated for the light-emitting devices obtained in Examples 9-16 and Comparative Examples 9-16. Brightness of each of Comparative Examples 9-16 is indicated as a relative value with respect to the result of corresponding one of Examples 9-16 set to 100%. The results are shown in Tables 2 and 3.

TABLE 1

| | | Composition of | Luminance |
|---|---|---|---|
| | Excitation light (nm) | blue light-emitting phosphor | (relative value) |
| Ex 1 | 410 | (Ba_{0.5}Sr_{0.4}Eu_{0.1})MgAl₁₀O₁₇ | 115.3% |
| Comp. | ″ | (Ba_{0.9}Eu_{0.1})MgAl₁₀O₁₇ | 100.0% |
| Ex 1 | | | |
| Ex 2 | 400 | (Ba_{0.25}Sr_{0.60}Eu_{0.15})MgAl₁₀O₁₇ | 121.2% |
| Comp. | ″ | (Ba_{0.85}Eu_{0.15})MgAl₁₀O₁₇ | 100.0% |
| Ex 2 | | | |
| Ex 3 | 420 | (Ba_{0.50}Sr_{0.30}Eu_{0.20})MgAl₁₀O₁₇ | 114.7% |
| Comp. | ″ | (Ba_{0.80}Eu_{0.20})MgAl₁₀O₁₇ | 100.0% |
| Ex 3 | | | |
| Ex 4 | 380 | (Ba_{0.20}Sr_{0.50}Ca_{0.10}Eu_{0.20})MgAl₁₀O₁₇ | 120.0% |
| Comp. | ″ | (Ba_{0.70}Ca_{0.10}Eu_{0.20})MgAl₁₀O₁₇ | 100.0% |
| Ex 4 | | | |
| Ex 5 | 430 | (Ba_{0.05}Sr_{0.80}Eu_{0.15})MgAl₁₀O₁₇ | 123.5% |
| Comp. | ″ | (Ba_{0.85}Eu_{0.15})MgAl₁₀O₁₇ | 100.0% |
| Ex 5 | | | |
| Ex 6 | 395 | (Ba_{0.60}Sr_{0.20}Eu_{0.20})MgAl₁₀O₁₇ | 111.9% |
| Comp. | ″ | (Ba_{0.80}Eu_{0.20}) MgAl₁₀O₁₇ | 100.0% |
| Ex 6 | | | |
| Ex 7 | 400 | (Ba_{0.30}Sr_{0.50}Eu_{0.20})(Mg_{0.99}Mn_{0.01})Al₁₀O₁₇ | 122.8% |
| Comp. | ″ | (Ba_{0.80}Eu_{0.20})(Mg_{0.99}Mn_{0.01})Al₁₀O₁₇ | 100.0% |
| Ex 7 | | | |
| Ex 8 | 410 | (Ba_{0.30}Sr_{0.60}Eu_{0.10})MgAl₁₀O₁₇ | 121.6% |
| Comp. | ″ | (Ba_{0.90}Eu_{0.10})MgAl₁₀O₁₇ | 100.0% |
| Ex 8 | | | |

TABLE 2

| | Primary | Composition of | Compositions of | | |
|---|---|---|---|---|---|
| | light | blue light-emitting | red light-emitting phosphor and | Brightness | |
| | (nm) | phosphor | green light-emitting phosphor | (relative value) | Tc-duv |
| Ex 9 | 410 | Ex 1 | red: (Ca_{0.99}Eu_{0.01})AlSiN₃ | 100% | 6850K |
| | | | green: (Ba_{0.85}Eu_{0.15})(Mg_{0.70}Mn_{0.30})Al₁₀O₁₇ | | −0.001 |
| Comp. | ″ | Comp. Ex 1 | red: (Ca_{0.99}Eu_{0.01})AlSiN₃ | 62% | 6850K |
| Ex 9 | | | green: (Ba_{0.85}Eu_{0.15})(Mg_{0.70}Mn_{0.30})Al₁₀O₁₇ | | −0.001 |
| Ex 10 | 400 | Ex 2 | red: (Ca_{0.985}Eu_{0.015})AlSiN₃ | 100% | 7100K |
| | | | green: 2(Ba_{0.60}Sr_{0.38}Eu_{0.02})O.SiO₂ | | +0.002 |
| Comp. | ″ | Comp. Ex 2 | red: (Ca_{0.985}Eu_{0.015})AlSiN₃ | 59% | 7100K |
| Ex 10 | | | green: 2(Ba_{0.60}Sr_{0.38}Eu_{0.02})O.SiO₂ | | +0.002 |
| Ex 11 | 420 | Ex 3 | red: (Ca_{0.94}Sr_{0.05}Eu_{0.01})AlSiN₃ | 100% | 5900K |
| | | | green: (Ba_{0.90}Eu_{0.10})(Mg_{0.65}Mn_{0.35})Al₁₀O₁₇ | | +0.002 |
| Comp. | ″ | Comp. Ex 3 | red: (Ca_{0.94}Sr_{0.05}Eu_{0.01})AlSiN₃ | 65% | 5900K |
| Ex 11 | | | green: (Ba_{0.90}Eu_{0.10})(Mg_{0.65}Mn_{0.35})Al₁₀O₁₇ | | +0.002 |
| Ex 12 | 380 | Ex 4 | red: (Ca_{0.99}Eu_{0.01})(Al_{0.90}Ga_{0.10})SiN₃ | 100% | 9000K |
| | | | green: 2(Ba_{0.65}Sr_{0.33}Ca_{0.01}Eu_{0.01})O.SiO₂ | | −0.001 |
| Comp. | ″ | Comp. Ex 4 | red: (Ca_{0.99}Eu_{0.01})(Al_{0.90}Ga_{0.10})SiN₃ | 60% | 9000K |
| Ex 12 | | | green: 2(Ba_{0.65}Sr_{0.33}Ca_{0.01}Eu_{0.01})O.SiO₂ | | −0.001 |

TABLE 3

| | Primary | Composition of | Compositions of | | |
|---|---|---|---|---|---|
| | light | blue light-emitting | red light-emitting phosphor and | Brightness | |
| | (nm) | phosphor | green light-emitting phosphor | (relative value) | Tc-duv |
| Ex 13 | 430 | Ex 5 | red: (Ca_{0.97}Ba_{0.01}Eu_{0.02})(Al_{0.99}In_{0.01})SiN₃ | 100% | 6100K |
| | | | green: (Ba_{0.50}Sr_{0.35}Eu_{0.15})(Mg_{0.80}Mn_{0.20})Al₁₀O₁₇ | | +0.002 |
| Comp. | ″ | Comp. Ex 5 | red: (Ca_{0.97}Ba_{0.01}Eu_{0.02})(Al_{0.99}In_{0.01})SiN₃ | 57% | 6100K |
| Ex 13 | | | green: (Ba_{0.50}Sr_{0.35}Eu_{0.15})(Mg_{0.80}Mn_{0.20})Al₁₀O₁₇ | | +0.002 |
| Ex 14 | 395 | Ex 6 | red: (Ca_{0.94}Sr_{0.05}Eu_{0.01})AlSiN₃ | 100% | 4200K |
| | | | green: 2(Ba_{0.55}Sr_{0.44}Eu_{0.01})O.SiO₂ | | −0.002 |
| Comp. | ″ | Comp. Ex 6 | red: (Ca_{0.94}Sr_{0.05}Eu_{0.01})AlSiN₃ | 67% | 4200K |
| Ex 14 | | | green: 2(Ba_{0.55}Sr_{0.44}Eu_{0.01})O.SiO₂ | | −0.002 |
| Ex 15 | 400 | Ex 7 | red: (Ca_{0.99}Eu_{0.01})AlSiN₃ | 100% | 5000K |
| | | | green: (Ba_{0.40}Sr_{0.40}Eu_{0.20})(Mg_{0.70}Mn_{0.30})Al₁₀O₁₇ | | +0.001 |
| Comp. | ″ | Comp. Ex 7 | red: (Ca_{0.99}Eu_{0.01})AlSiN₃ | 58% | 5000K |
| Ex 15 | | | green: (Ba_{0.40}Sr_{0.40}Eu_{0.20})(Mg_{0.70}Mn_{0.30})Al₁₀O₁₇ | | +0.001 |
| Ex 16 | 410 | Ex 8 | red: (Ca_{0.985}Eu_{0.015})AlSiN₃ | 100% | 6700K |
| | | | green: (Sr_{0.99}Eu_{0.01})O.Al₂O₃ | | +0.001 |
| Comp. | ″ | Comp. Ex 8 | red: (Ca_{0.985}Eu_{0.015})AlSiN₃ | 64% | 6700K |
| Ex 16 | | | green: (Sr_{0.99}Eu_{0.01})O.Al₂O₃ | | +0.001 |

As shown in Table 1, in the blue light-emitting phosphors of Examples 1-8, luminance is significantly improved compared to the blue light-emitting phosphors of Comparative Examples 1-8. Further, as shown in Tables 2 and 3, in the light-emitting devices of Examples 9-16, brightness in the similar color temperature is considerably improved compared to those of Comparative Examples 9-16. It is understood that the light-emitting device of the present invention has stable chromaticity and high luminance.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A blue light-emitting phosphor, comprising a divalent europium-activated or divalent europium- and manganese-activated aluminate phosphor, substantially represented by the following general formula (1):
a[(MI_{1-c-d}Sr_{c}Eu_{d})(Mg₁₋ₑMnₑ)]O.bAl₂O₃ (1)
(in the formula (1), MI represents at least one kind of element selected from Ca and Ba, and a, b, c, d and e are numbers satisfying 0.1≦a/b≦1.0, 0.2≦c≦0.8, 0.01≦d≦0.5, and 0≦e≦0.05).

2. The blue light-emitting phosphor according to claim 1, wherein MI is Ba.

3. The blue light-emitting phosphor according to claim 1, comprising the divalent europium-activated aluminate phosphor, with e being 0.

4. A light-emitting device, comprising:
a light-emitting element emitting primary light; and
a wavelength conversion unit absorbing at least part of said primary light and emitting secondary light having a wavelength equal to or longer than a wavelength of said primary light;
said wavelength conversion unit being made of at least one kind of phosphor, and said phosphor including the blue light-emitting phosphor as recited in claim 1.

5. The light-emitting device according to claim 4, wherein said light-emitting element is a gallium nitride (GaN)-based semiconductor, and said primary light emitted from said light-emitting element has a peak wavelength in a range from 380 nm to 430 nm.

6. The light-emitting device according to claim 4, wherein said wavelength conversion unit is made of the blue light-emitting phosphor, a green light-emitting phosphor and a red light-emitting phosphor, and in a light path of said wavelength conversion unit, said phosphors are stacked in order from the one emitting the secondary light of longer wavelength.

7. The light-emitting device according to claim 6, wherein said green light-emitting phosphor includes at least one kind of phosphor selected from:
a divalent europium- and manganese-activated aluminate phosphor substantially represented by the following general formula (2):
a(MII,Eu_{f},Mn_{g})O.bAl₂O₃ (2)
(in the formula (2), MII represents at least one kind of element selected from Mg, Ca, Sr, Ba and Zn, and a, b, f and g are numbers satisfying a>0, b>0, 0.1≦a/b≦1.0, and 0.3≦g/f≦5.0);
a divalent europium-activated silicate phosphor substantially represented by the following general formula (3):
2(MIII₁₋ₕEuₕ)O.SiO₂ (3)
(in the formula (3), MIII represents at least one kind of element selected from Mg, Ca, Sr and Ba, and h is a number satisfying 0.005≦h≦0.10); and
a divalent europium-activated strontium aluminate phosphor substantially represented by the following general formula (4):
(Sr₁₋ₘEuₘ)O.Al₂O₃ (4)
(in the formula (4), m is a number satisfying 0.0001≦m≦0.3).

8. The light-emitting device according to claim 6, wherein said red light-emitting phosphor includes a divalent europium-activated nitride phosphor substantially represented by the following general formula (5):
(MIII₁₋ₖEuₖ)MIVSiN₃ (5)
(in the formula (5), MIII represents at least one kind of element selected from Mg, Ca, Sr and Ba, MIV represents at least one kind of element selected from Al, Ga, In, Sc, Y, La, Gd and Lu, and k is a number satisfying 0.001≦k≦0.05).
